(19) United States
(12) Patent Application Publication
(10) Pub. No.: US 2026/0358396 A1
(43) Pub. Date: Nov. 12, 2026

(54) SYSTEM AND METHOD FOR MEASURING EM PROPERTY SUCH AS NOISE FIGURE OR GAIN

(71) Applicant: ANTENNEX HOLDING B.V., Eindhoven (NL)

(72) Inventors: Timotheüs STEK, Eindhoven (NL); Anouk HUBRECHSEN, Eindhoven (NL)

(21) Appl. No.: 19/486,292

(22) PCT Filed: May 17, 2024
(86) PCT No.: PCT/NL2024/050250

§ 371 Date: Nov. 20, 2025

(30) Foreign Application Priority Data
May 22, 2023 (NL) 2034880

(51) Int. Cl. G01R 29/26; G01R 29/08

(52) U.S. Cl. CPC G01R 29/26; G01R 29/0821

(57) ABSTRACT

A system for measuring a noise figure of a device-under-test (DUT). The system may comprise a reverberation chamber, configured to receive the DUT, and a first antenna positioned within the reverberation chamber and a second antenna positioned within the reverberation chamber. The first antenna may be arranged to output EM radiation, when coupled with an EM radiation source, in a first phase and in a second phase. The system may further comprise a measurement module configured to be coupled with the second antenna in the first phase and with the DUT in the second phase. The measurement module may be configured to measure an EM radiation level in the reverberation chamber during the first phase; and to measure the noise figure of the DUT during the second phase, based on the EM radiation level measured in the reverberation chamber during the first phase.

### TECHNICAL FIELD

The present disclosure relates to the field of electromagnetic testing, and more specifically, to a reverberation chamber for evaluating the performance of electronic devices, antennas, and other equipment in a controlled environment. Particular embodiments relate to a system and a method for measuring a noise figure of a device-under-test.

### BACKGROUND

A reverberation chamber is a type of electromagnetic (EM) testing facility that is used to evaluate the performance of electronic devices, antennas, and other equipment in a controlled environment.

The chamber is typically a metal room that is designed to reflect electromagnetic waves in a way that creates a statistically uniform field within the space. The walls, ceiling, and floor of the chamber are covered with or made from a material that reflects any incoming electromagnetic waves, which causes them to bounce around the chamber for an extended period of time. This creates a “reverberant” field, where the waves overlap and interfere with each other in a chaotic manner—hence the name: “reverberation chamber”.

The reverberation chamber can be used for a variety of testing applications, including measuring the EM compatibility (EMC) of electronic devices, determining the radiation characteristics of antennas, and evaluating the performance of wireless communication systems.

One of the advantages of a reverberation chamber is that it allows for testing in a highly repeatable environment from a statistical point of view. Because the field inside the chamber is statistically uniform and isotropic when averaged across a plurality of measurements with different reflective conditions in the reverberation chamber, it is less sensitive to the positioning of the test equipment than other types of test environments. This makes it easier to conduct experiments and measurements that are consistent and reliable.

In the context of EM testing, a noise figure (NF) or noise factor (F) is a measure of how much additional noise a device-under-test (DUT) adds to a signal as the signal passes through the device. The noise factor is expressed as a ratio of input/output signal-to-noise ratio (SNR) on a linear scale and is therefore unitless. The noise figure, on the other hand, is a 10-log version of the noise factor and is expressed in dB.

A device with a lower noise figure adds less additional noise to a signal as the signal passes through the device, compared to a device with a higher noise figure. The noise figure is an important parameter to measure and optimize in the design and testing of electronic devices, particularly in applications where low signal powers are expected, such as in wireless communications or radar systems.

Most commonly, the noise figure of wireless and/or integrated devices is measured using a method based on the so-called Y-Factor method. This radiometric method can be applied using the sky outside as a reference for the measurement. However, environmental conditions such as weather and human-made interference create a non-ideal testing environment and create large uncertainties in the measurement results.

In the context of wireless and/or integrated devices, noise figure can be a critical metric. There is therefore a need for more accurate measurement setups and methods for determining the noise figure of wireless and/or integrated devices.

### SUMMARY

In a reverberation chamber, the noise figure can be measured by injecting a known noise power level into the DUT and measuring the output signal with a spectrum analyzer or some other test equipment. The noise figure can then be calculated from the measured SNR or noise power values using the appropriate formulas. By measuring the noise figure of a DUT, a user of the system can evaluate the device's performance and identify areas for improvement.

According to an aspect of the present disclosure, there is provided a system for measuring a noise figure of a device-under-test, DUT. The system comprises a reverberation chamber, configured to receive the DUT, and a first antenna positioned within the reverberation chamber and a second antenna positioned within the reverberation chamber. The first antenna is arranged to output EM radiation, when coupled with an EM radiation source, in a first phase and in a second phase. The system further comprises a measurement module configured to be coupled with the second antenna in the first phase and with the DUT in the second phase. The measurement module is configured to measure an EM radiation level in the reverberation chamber during the first phase; and to measure the noise figure of the DUT during the second phase, based on the EM radiation level measured in the reverberation chamber during the first phase.

The system allows to output, via the first antenna, EM radiation based on a signal from an EM radiation source (which may be comprised as an integral part of the system, or which may simply be coupled to the antenna). This EM radiation may be used to create at least one EM radiation level in the reverberation chamber, for example one or two noise power levels.

The EM radiation power level in the reverberation chamber can be measured by means of a calibration measurement, where a second, reference antenna is used to measure a power level reflecting the power level at the input of the antenna, i.e., at the DUT. The device that is inside the reverberation chamber is therefore exposed to an environment with a known noise power level. The received power of the DUT can then be measured. In other words, based on the EM radiation level (e.g. the noise power level), the noise figure of the DUT can be determined.

In other words, the use of a reference antenna in the calibration step may help to simplify the measurement of one or more EM property or properties of the DUT, as this removes the need to perform several calibration steps, avoiding an expensive piece of instrumentation (a vector network analyzer).

Moreover, the setup of the measurement system does not need to be changed for the second phase compared to the first phase, since both the DUT and the second antenna can remain in the reverberation chamber. This not only simplifies the method but also increases the measurement accuracy of the setup, since the reflective behavior inside the reverberation chamber is consistent when measuring with the second antenna and the DUT.

The first phase may be termed a calibration phase, and the second phase may be termed a measurement phase, but these terms are only meant as handy names and are not meant to be limiting.

In a preferred embodiment, the EM radiation may be noise. In an alternative embodiment, the EM radiation may be a non-noise signal. In a particularly preferred embodiment, that non-noise signal preferably has a low power. In an alternative embodiment, the EM radiation may be a non-noise signal that has a high power.

In a particular embodiment, the system comprises the EM radiation source, coupled with the first antenna, and the EM radiation source is configured to cause the first antenna to output the EM radiation in at least one EM frequency range, at exactly one EM radiation level on condition that system gain of the DUT is known, or at at least three EM radiation levels. In either case, efficiency of the second antenna should also be known. Furthermore, it is noted that the system gain of the DUT and/or the efficiency of the second antenna need not be known prior to measuring the noise figure of the DUT but may be measured afterwards—in that case too, they can still be considered to be known.

It is of course possible to use two EM radiation levels, but using just one may be more efficient, and using three or more may afford better accuracy.

In a particular embodiment, the second antenna is tuned to a frequency range corresponding with the at least one EM frequency range.

In a particular embodiment, the EM radiation source is operable at selectively a first, P_hot, or a second, P_cold EM radiation temperature.

In a particular embodiment, the system comprises at least one load termination configured to be coupled with the DUT in the first phase and with the second antenna in the second phase.

In a particular embodiment, the at least one load termination has an impedance that is matched to an impedance of the DUT or to an impedance of the second antenna.

In a particular embodiment, the system comprises at least one additional antenna configured equivalently to the second antenna.

In a particular embodiment, the measurement module comprises a spectrum analyzer. Alternatively, the measurement module may comprise any suitable power detector responsive to the frequency band of interest.

In a particular embodiment, the EM radiation source comprises: an optional signal and/or noise generator; an amplifier; and a preferably variable attenuator. In other words, the EM radiation source may comprise just an amplifier and an attenuator, or it may comprise a signal and/or noise generator, an amplifier and an attenuator. In either case, the attenuator may be fixed or may be variable.

In a particular embodiment, the EM radiation source is configured to generate the signal for the first antenna to output EM radiation by deactivating the signal generator. In another particular embodiment, the noise generator can be activated or deactivated to generate two noise power levels.

According to another aspect of the present disclosure, there is provided a method for measuring a noise figure of a device-under-test, DUT. The method comprises the following steps:
placing the DUT in a reverberation chamber;
providing a first antenna positioned within the reverberation chamber;
providing a second antenna positioned within the reverberation chamber;
outputting EM radiation via the first antenna, in a first phase and in a second phase;
measuring, during the first phase, an EM radiation level in the reverberation chamber, via the second antenna; and
measuring the noise figure of the DUT, during the second phase, based on the EM radiation level measured in the reverberation chamber during the first phase.

The skilled person will appreciate that considerations and advantages described above with regard to embodiments of the system according to the present disclosure will apply mutatis mutandis to embodiments of the method according to the present disclosure.

The first phase may be termed a calibration phase, and the second phase may be termed a measurement phase, but these terms are only meant as handy names and are not meant to be limiting.

In a preferred embodiment, the EM radiation may be noise. In an alternative embodiment, the EM radiation may be a non-noise signal that preferably has a low power.

In a particular embodiment, the step of outputting the EM radiation comprises outputting the EM radiation in at least one EM frequency range, at exactly one EM radiation level on condition that system gain of the DUT is known, or at at least three EM radiation levels. In either case, efficiency of the second antenna should also be known. Furthermore, it is noted that the system gain of the DUT and/or the efficiency of the second antenna need not be known prior to measuring the noise figure of the DUT but may be measured afterwards—in that case too, they can still be considered to be known.

It is of course possible to use two EM radiation levels, but using just one may be more efficient, and using three or more may afford better accuracy.

In a particular embodiment, the step of outputting the EM radiation comprises outputting the EM radiation at selectively a first, P_hot, or a second, P_cold, EM radiation temperature.

In a particular embodiment, the method comprises coupling at least one load termination with the DUT in the first phase and with the second antenna in the second phase.

In a particular embodiment, the method comprises providing at least one additional antenna configured equivalently to the second antenna.

In a particular embodiment, the method comprises providing a EM radiation source comprising: an optional signal and/or noise generator; an amplifier; and a preferably variable attenuator. In other words, the EM radiation source may comprise just an amplifier and an attenuator, or it may comprise a signal and/or noise generator, an amplifier, and an attenuator. In either case, the attenuator may be fixed or may be variable. If a particular embodiment is an embodiment including the signal generator, the method may further comprise deactivating the signal generator in order to generate signal for the first antenna to output the EM radiation.

In a particular embodiment, the method comprises coupling a measurement module with the second antenna in the first phase and with the DUT in the second phase, and performing the two steps of measuring using the measurement module.

Any considerations and advantages applying to any embodiment of the system according to the present disclosure may apply mutatis mutandis to any embodiments of the method according to the present disclosure, and vice versa.

In any embodiment according to the present disclosure, at least one mode stirring mechanism may be included within the reverberation chamber. The at least one mode stirring mechanism may be mechanical and/or electronic. Alternatively or even additionally, it is also possible to do position stirring inside a reverberation chamber. Position stirring involves that, instead of using a stirrer to change the modes, a position of the antenna is changed inside the chamber and probing is then done at different locations.

### BRIEF DESCRIPTION OF THE DRAWINGS

The above-described illustrative embodiments will be more fully understood with the help of the appended drawings, in which:

FIG. 1 schematically illustrates an embodiment of a system according to the present disclosure, as operated during a first phase;

FIG. 2 schematically illustrates an embodiment of a system according to the present disclosure, as operated during a second phase; and

FIG. 3 shows a flowchart illustrating an embodiment of a method according to the present disclosure.

### DETAILED DESCRIPTION

The following description provides a detailed overview of the construction and operation of various embodiments according to the present disclosure, including their various components, test procedures, and data analysis methods. Specific embodiments and examples are provided to illustrate the invention, but it should be understood that the invention is not limited to these examples and can be adapted and modified as necessary. In particular, one or more features of particular embodiments may be combined with other embodiments if the skilled person would understand that this new combination would be functional.

The specific testing procedure for a device-under-test (DUT) in a reverberation chamber may depend on the nature of the device and the particular testing requirements. However, a typical testing procedure may be performed as follows:
1. Preparation: Before the testing begins, the DUT may be mounted on a test fixture or positioned within the chamber. Any necessary cables or other connections may be made.
2. Calibration: The chamber may be calibrated to ensure that the electromagnetic field inside is statistically uniform and well-controlled. This may involve measuring the field strength at various points in the chamber using a specialized probe.
3. Initial measurement: The DUT may be powered on, and an initial measurement may be taken to establish a baseline for its performance. This measurement may include a range of parameters, such as radiation patterns, efficiency, or susceptibility to interference.
4. Test signals: The DUT may be subjected to a series of test signals, which are designed to evaluate its performance under different conditions. These signals may include both narrowband and broadband signals, as well as signals with different modulations or power levels.
5. Data collection: During the testing, data may be collected on the DUT's performance under each test signal. This may include measurements of signal strength, distortion, noise, or other parameters. The data may typically be recorded and analyzed using specialized software.
6. Analysis and interpretation: Once the testing is complete, the data may be analyzed to determine whether the DUT meets the required performance specifications. This may involve comparing the measured parameters to the device's datasheet or to industry standards. Any deviations from the expected performance may be noted and investigated further.
7. Reporting: Finally, a report may be generated summarizing the testing procedure and results. The report may include detailed information on the test setup, the test signals used, and the measured data, as well as any recommendations for further testing or improvement of the DUT.

Receiving systems for mm-wave applications are in general increasing in complexity and level of integration. Therefore, crucial metrics such as noise figure or gain have to be characterized using an over-the-air approach. The present disclosure at least in part relates to a simplified version the reverberation-chamber noise-figure (RCN) method, wherein fewer calibration steps and fewer alterations of the measurement setup are necessary for the measurement of EM properties such as the noise figure and gain. This can increase measurement accuracy compared to conventional measurement setups and methods.

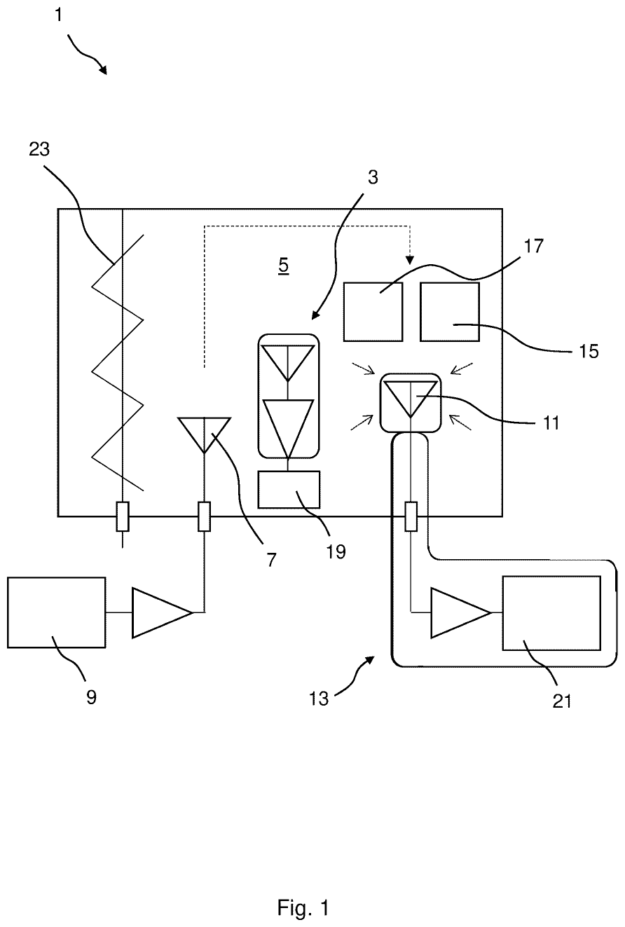

FIG. 1 schematically illustrates an embodiment of a system 1 according to the present disclosure, as operated during a first phase. System 1 is suitable for measuring a noise figure of a device-under-test, DUT 3. System 1 may comprise a reverberation chamber 5, configured to receive DUT 3, and a first antenna 7 positioned within the reverberation chamber 5 and a second antenna 11 positioned within the reverberation chamber 5. First antenna 7 may be arranged to output EM radiation, when coupled with an EM radiation source 9, in a first phase and in a second phase. System 1 may further comprise a measurement module 13 configured to be coupled with second antenna 11 in the first phase and with DUT 3 in the second phase. Measurement module 13 may be configured to measure an EM radiation level in reverberation chamber 5 during the first phase; and to measure the noise figure of DUT 3 during the second phase, based on the EM radiation level measured in reverberation chamber 5 during the first phase.

As already stated above, in a particularly preferred embodiment, the EM radiation may be noise. In an alternative embodiment, the EM radiation may be a non-noise signal that preferably has a low power.

In a particular embodiment, system 1 may comprise EM radiation source 9, coupled with first antenna 7, and EM radiation source 9 may be configured to cause first antenna 7 to output the EM radiation in at least one EM frequency range, at exactly one EM radiation level on condition that system gain of DUT 3 is known, or at at least three EM radiation levels. In either case, efficiency of the second antenna should also be known.

It is of course possible to use two EM radiation levels, but using just one may be more efficient, and using three or more may afford better accuracy.

FIG. 1 schematically shows the use of two EM radiation levels, just as an example. These two EM radiation levels are shown using reference signs 15 and 17. In other words, EM radiation source 9 may be operable at selectively a first, P_hot 15, or a second, P_cold 17, EM noise temperature. P_hot is typically used to indicate a high level of noise, whereas P_cold is typically used to indicate a low level of noise. Using two levels of measurement allows to determine system gain (i.e., efficiency) and noise figure of DUT 3 (two unknowns, two knowns). However, it is of course possible to measure system gain of DUT 3 in different ways. In that case, if system gain of DUT 3 is known, one EM radiation level (e.g. one noise level) would suffice to solve this system of unknowns. In other words, the noise figure of DUT 3 can be determined based on one or two power levels of the EM radiation (e.g. the noise) in reverberation chamber 5. Nevertheless, more EM radiation levels might be used in order to further improve accuracy.

As explained above, only one calibration measurement is in principle required in this manner. This can be achieved by placing DUT 3 with an optional load termination 19 in reverberation chamber 5 during the first phase, which may function as a calibration measurement, and by placing any suitable second antenna 11 (tuned for the frequency range of interest and having a known efficiency) with an optional load termination 19 in the reverberation chamber 5 during the second phase, which may function as a DUT measurement. In principle, there are no limits to position or placement within reverberation chamber 5, within the “working volume” of the chamber.

The efficiency of an antenna relates to how well it converts the electrical power supplied to it into radiated electromagnetic energy. It represents the ratio of the power radiated by the antenna to the total power supplied to it (which includes both the radiated power and any power losses within the antenna system). Efficiency can be expressed as a percentage and may be affected by various factors such as the antenna's design, materials used, construction techniques, and environmental conditions. Higher efficiency means that a larger portion of the power supplied to the antenna is converted into useful radiation, resulting in improved overall performance.

Second antenna 11 can in general be a passive antenna, meaning that the efficiency in receive mode and transmit mode is the same as a result of reciprocity.

In a particular embodiment, second antenna 11 may be tuned to a frequency range corresponding with the at least one EM frequency range.

In a particular embodiment, system 1 may comprise at least one load termination 19 configured to be coupled with DUT 3 in the first phase and with second antenna 11 in the second phase. In FIG. 1, this optional at least one load termination 19 is shown to be coupled with DUT 3 in the first phase.

In a particular embodiment, the at least one load termination 19 may have an impedance that is matched to an impedance of DUT 3 or to an impedance of the second antenna 11. The at least one load termination 19 may for example have an impedance of around 50 ohms, but any value could be conceivable. In a further developed embodiment, there may be multiple load terminations 19 (only one is shown in FIG. 1), which may reduce the need to move one single load termination 19. If just a single load termination 19 is used, it may for example be moved between the first and the second phase, and/or its cabling may for example be re-routed between those phases.

In a particular embodiment, system 1 may comprise at least one additional antenna (not shown in FIG. 1) configured equivalently to second antenna 11. This may help to reduce measurement uncertainty.

In a particular embodiment, measurement module 13 may comprise a spectrum analyzer 21. Alternatively, measurement module 13 may comprise any suitable power detector responsive to the frequency band of interest.

In a particular embodiment, EM radiation source 9 may comprise: an optional signal and/or noise generator; an amplifier; and a preferably variable attenuator. In other words, the EM radiation source may comprise just an amplifier and an attenuator, or it may comprise a signal and/or noise generator, an amplifier, and an attenuator. In either case, the attenuator may be fixed or may be variable. The internal details of these various particular embodiments are not illustrated, but the skilled person will find no difficulty in arranging them structurally and functionally within system 1.

It is also noted that the amplifier may be integrated in the signal and/or noise generator.

EM radiation source 9 can in other words be easily used as a signal generator or a noise generator, allowing for various types of measurements to be carried out.

In a particular, further developed embodiment, EM radiation source 9 may be configured to generate the signal for the first antenna to output EM radiation by deactivating the signal generator. In other words, to create noise or a signal, the signal generator may for example be turned off and on, respectively. In another embodiment the noise generator may be activated or deactivated to generate two noise power levels.

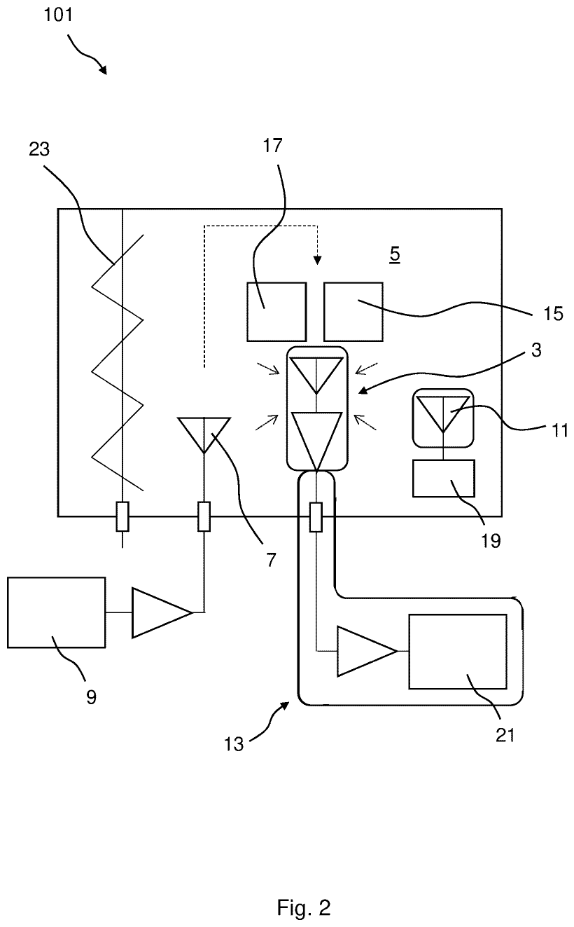

In other words, in the first phase, as shown in FIG. 1, which may also be termed a calibration, a transmitting antenna, i.e. first antenna 7, may transmit the EM radiation (e.g. noise or signal power) in reverberation chamber 5, DUT 3 may be placed in reverberation chamber 5 and may optionally be terminated with a load termination 19 (e.g. a load of 50 ohms), and a receiving antenna, i.e. second antenna 11, may be used to measure the EM radiation (e.g. noise) power level inside the reverberation chamber 5. After the first phase, so after the calibration, the EM radiation (e.g. noise) power level in reverberation chamber 5 should be known. Based on the known EM radiation (e.g. noise) power level in reverberation chamber 5, the noise figure of the DUT can be determined, by performing a DUT measurement in the second phase, shown in FIG. 2 and described below. If two or more power levels are used, system gain can also be determined.

FIG. 2 schematically illustrates an embodiment of a system 101 according to the present disclosure, as operated during a second phase. System 101 of FIG. 2 corresponds with system 1 of FIG. 1, except in that the figure shows the second phase instead of the first phase. Therefore, measurement module 13 is shown to be coupled with DUT 3 instead of with second antenna 11 as in the first phase (as in FIG. 1). Moreover, but this is optional, the at least one load termination 19 is shown to be coupled with the second antenna instead of with DUT 3 as in the first phase (as in FIG. 1).

In other words, in the second phase, as shown in FIG. 2, which may also be termed a DUT measurement, measurement module 13 may be connected to the DUT 3, second antenna 11 may be terminated with an optional load termination (e.g. a load of 50 ohms), and first antenna 7 may preferably be left connected to an EM radiation source, such as a noise source. By measuring the output power in the DUT measurement, the noise figure of the DUT can be determined.

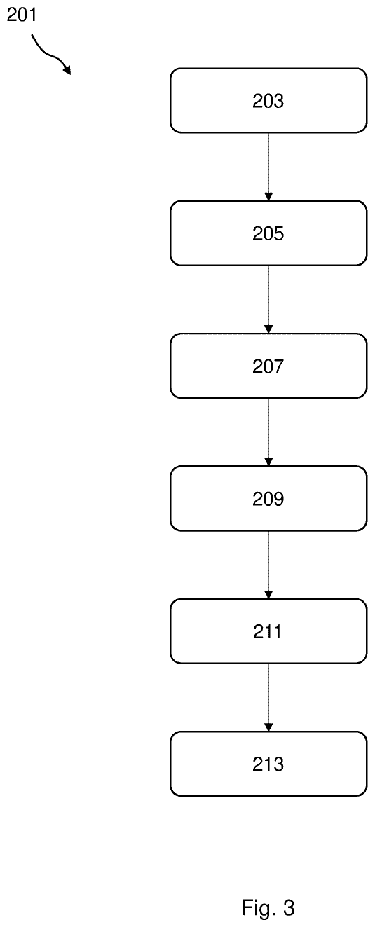

FIG. 3 shows a flowchart illustrating an embodiment of a method according to the present disclosure.

The method 201 for measuring a noise figure of a device-under-test, DUT. The method 201 may comprise the following steps:
placing 203 the DUT in a reverberation chamber;
providing 205 a first antenna positioned within the reverberation chamber;
providing 207 a second antenna positioned within the reverberation chamber;
outputting 209 EM radiation via the first antenna, in a first phase and in a second phase;
measuring 211, during the first phase, an EM radiation level in the reverberation chamber, via the second antenna; and
measuring 213 the noise figure of the DUT, during the second phase, based on the EM radiation level measured in the reverberation chamber during the first phase.

In various further developed embodiments, method 201 shown in FIG. 3 may be expanded with any one or more of the steps described above. The skilled person will find no difficulty in integrating those additional steps into the flowchart depicted in FIG. 3.

In any embodiment according to the present disclosure, at least one mode stirring mechanism may be included within the reverberation chamber, such as mode stirring mechanism 23. Alternatively or even additionally, it is also possible to do position stirring inside a reverberation chamber. Position stirring involves that, instead of using a mode stirring mechanism to change the modes, a position of the antenna is changed inside the chamber and probing is then done at different locations.

None of the embodiments described herein are limited to specific frequency bands. In addition to the above-described embodiments, the present disclosure may also relate to any of the following clauses.
Clause 1. A system for measuring an electromagnetic, EM, property, such as a noise figure or a gain, of a device-under-test, DUT; the system comprising:
a reverberation chamber configured to receive the DUT;
a first antenna positioned within the reverberation chamber and arranged to output EM radiation, when coupled with an EM radiation source, in a first phase and in a second phase;
a second antenna positioned within the reverberation chamber; and
a measurement module configured to be coupled with the second antenna in the first phase and with the DUT in the second phase;
wherein the measurement module is configured to:
measure an EM radiation level in the reverberation chamber during the first phase; and
measure the EM property of the DUT during the second phase, based on the EM radiation level measured in the reverberation chamber during the first phase.
   Clause 2. The system of clause 1, comprising the EM radiation source, coupled with the first antenna;
wherein the EM radiation source is configured to output the EM radiation in at least one EM frequency range, at exactly one EM radiation level on condition that system gain of the DUT is known, or at at least three EM radiation levels.
   Clause 3. The system of clause 2, wherein the second antenna is tuned to a frequency range corresponding with the at least one EM frequency range.
   Clause 4. The system of any of the clauses 1-3, wherein the EM radiation source is operable at selectably a first, P_hot, or a second, P_cold, EM radiation noise temperature.
   Clause 5. The system of any of the clauses 1-4, comprising at least one load termination configured to be coupled with the DUT in the first phase and with the second antenna in the second phase.
   Clause 6. The system of clause 5, wherein the at least one load termination has an impedance that is matched to an impedance of the DUT or to an impedance of the second antenna.
   Clause 7. The system of any of the clauses 1-6, comprising at least one additional antenna configured equivalently to the second antenna.
   Clause 8. The system of any of the clauses 1-7, wherein the measurement module comprises a spectrum analyser.
   Clause 9. The system of any of the clauses 1-8, wherein the EM radiation source comprises:
an optional signal and/or noise generator;
an amplifier; and
a preferably variable attenuator.
   Clause 10. The system of clause 9, wherein the EM radiation source is configured to generate the EM radiation by deactivating the signal generator.
   Clause 11. A method for measuring an electromagnetic, EM, property, such as a noise figure or a gain, of a device-under-test, DUT; the method comprising:
placing the DUT in a reverberation chamber;
providing a first antenna positioned within the reverberation chamber;
providing a second antenna positioned within the reverberation chamber;
outputting EM radiation via the first antenna, in a first phase and in a second phase;
measuring, during the first phase, an EM radiation level in the reverberation chamber, via the second antenna; and
measuring the EM property of the DUT, during the second phase, based on the EM radiation level measured in the reverberation chamber during the first phase.
   Clause 12. The method of clause 11, wherein the step of outputting the EM radiation comprises outputting the EM radiation in at least one EM frequency range, at exactly one EM radiation level on condition that system gain of the DUT is known, or at at least three EM radiation levels.
   Clause 13. The method of clause 11 or 12, wherein the step of outputting the EM radiation comprises outputting the EM radiation at selectably a first, P_hot, or a second, P_cold, EM radiation temperature.
   Clause 14. The method of any of the clauses 11-13, comprising coupling at least one load termination with the DUT in the first phase and with the second antenna in the second phase.
   Clause 15. The method of any of the clauses 11-14, comprising providing at least one additional antenna configured equivalently to the second antenna.
   Clause 16. The method of any of the clauses 11-15, comprising providing a EM radiation source comprising: an optional signal and/or noise generator; an amplifier; and a preferably variable attenuator; the method optionally further comprising deactivating the signal generator in order to generate the EM radiation.
   Clause 17. The method of any of the clauses 11-16, comprising coupling a measurement module with the second antenna in the first phase and with the DUT in the second phase, and performing the two steps of measuring using the measurement module.

In the above description, the present disclosure has been explained using detailed embodiments thereof. However, the present disclosure is not limited to these embodiments, and various modifications can be implemented without deviating from the scope of the present disclosure as defined by the appended claims and, in some jurisdictions, their equivalents.

1.-17. (canceled)

18. A system for measuring a noise figure of a device-under-test, DUT, the system comprising:
a reverberation chamber;
a first antenna configured to output EM radiation, when coupled with an EM radiation source, in a first phase and in a second phase;
a second antenna; and
a measurement module configured to be coupled with the second antenna in the first phase and with the DUT in the second phase,
wherein the DUT, the first antenna, and the second antenna are configured to be arranged in the reverberation chamber during the first phase and the second phase, and
wherein the measurement module is configured to:
measure an EM radiation level in the reverberation chamber during the first phase; and
measure the noise figure of the DUT during the second phase, based on the EM radiation level measured in the reverberation chamber during the first phase.

19. The system of claim 18, comprising the EM radiation source, coupled with the first antenna,
wherein the EM radiation source is configured to cause the first antenna to output the EM radiation in at least one EM frequency range, at exactly one EM radiation level on condition that system gain of the DUT is known, or at at least three EM radiation levels.

20. The system of claim 19, wherein the second antenna is tuned to a frequency range corresponding with the at least one EM frequency range.

21. The system of claim 18, wherein the EM radiation source is operable at selectively a first, P_hot, or a second, P_cold, EM radiation noise temperature.

22. The system of claim 18, comprising at least one load termination configured to be coupled with the DUT in the first phase and with the second antenna in the second phase.

23. The system of claim 22, wherein the at least one load termination has an impedance that is matched to an impedance of the DUT or to an impedance of the second antenna.

24. The system of claim 18, comprising at least one additional antenna configured equivalently to the second antenna.

25. The system of claim 18, wherein the measurement module comprises a spectrum analyzer.

26. The system of claim 18, wherein the EM radiation source comprises:
an optional signal and/or noise generator;
an amplifier; and
a preferably variable attenuator.

27. The system of claim 26, wherein the EM radiation source is configured to generate a signal for the first antenna to output the EM radiation by deactivating the signal generator.

28. A method for measuring a noise figure of a device-under-test, ‘DUT’, the method comprising:
placing the ‘DUT’ in a reverberation chamber;
providing a first antenna positioned within the reverberation chamber;
providing a second antenna positioned within the reverberation chamber;
outputting EM radiation via the first antenna, in a first phase and in a second phase, wherein the DUT, the first antenna, and the second antenna are arranged in the reverberation chamber during the first phase and the second phase;
measuring, during the first phase, an EM radiation level in the reverberation chamber, via the second antenna; and
measuring the noise figure of the DUT, during the second phase, based on the EM radiation level measured in the reverberation chamber during the first phase.

29. The method of claim 28, wherein the step of outputting the EM radiation comprises outputting the EM radiation in at least one EM frequency range, at exactly one EM radiation level on condition that system gain of the DUT is known, or at at least three EM radiation levels.

30. The method of claim 28, wherein the step of outputting the EM radiation comprises outputting the EM radiation at selectively a first, P_hot, or a second, P_cold, EM radiation temperature.

31. The method of claim 28, comprising coupling at least one load termination with the DUT in the first phase and with the second antenna in the second phase.

32. The method of claim 28, comprising providing at least one additional antenna configured equivalently to the second antenna.

33. The method of claim 28, comprising providing an EM radiation source comprising: an optional signal and/or noise generator; an amplifier; and a preferably variable attenuator; the method optionally further comprising deactivating the signal generator in order to generate the EM radiation.

34. The method of claim 28, comprising coupling a measurement module with the second antenna in the first phase and with the DUT in the second phase, and performing the two steps of measuring using the measurement module.
